(19) United States
(12) Patent Application Publication
(10) Pub. No.: US 2025/0102567 A1
(43) Pub. Date: Mar. 27, 2025

(54) CHIP ELECTRICAL PROPERTY DETECTION DEVICE AND METHOD OF MANUFACTURING THE SAME

(71) Applicant: ASTI GLOBAL INC., TAIWAN, Taichung City (TW)

(72) Inventor: CHIEN-SHOU LIAO, Taichung City (TW)

(21) Appl. No.: 18/827,857

(22) Filed: Sep. 9, 2024

Related U.S. Application Data
(60) Provisional application No. 63/540,380, filed on Sep. 26, 2023.

(51) Int. Cl. G01R 31/28

(52) U.S. Cl. CPC G01R 31/2887

(57) ABSTRACT

A chip electrical property detection device and a method of manufacturing the same are provided. The chip electrical property detection device includes a structural strengthening module, an electrical detection module and a flexible buffer structure. The structural strengthening module includes a structural strengthening substrate. The flexible buffer structure includes a flexible buffer material layer. The structural strengthening module, the electrical detection module and the flexible buffer structure are configured to cooperate with each other to form the chip electrical property detection device. The probe carrying substrate is disposed on the flexible buffer material layer, and the electrical detection structures are respectively disposed on the probe carrying substrate and electrically connected to the electrical connection structures. The probe carrying substrate can be configured to be slightly adjusted through the flexible buffer material layer, thereby allowing each electrical detection structure to be slightly adjusted following the probe carrying substrate.

### CROSS-REFERENCE TO RELATED PATENT APPLICATION

This application claims the benefit of priority to the U.S. Provisional Patent Application Ser. No. 63/540,380, filed on Sep. 26, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a detection device and a method of manufacturing the same, and more particularly to a chip electrical property detection device and a method of manufacturing the same.

### BACKGROUND OF THE DISCLOSURE

In the related art, during the lighting test of wafer-level micro LED chips or mini LED chips, multiple LED chips will be sequentially tested and screened one by one through the power supply of the probe detection device, but the testing and screening speed is quite slow. If multiple probe detection devices are used to supplement the testing speed, the production cost will be increased and the overall production efficiency will be very low.

### SUMMARY OF THE DISCLOSURE

In response to the above-referenced technical inadequacy, the present disclosure provides a chip electrical property detection device and a method of manufacturing the same.

In order to solve the above-mentioned problems, one of the technical aspects adopted by the present disclosure is to provide a chip electrical property detection device, which includes a structural strengthening module, an electrical detection module and a flexible buffer structure. The structural strengthening module includes a structural strengthening substrate. The electrical detection module includes a probe carrying substrate, a plurality of electrical detection structures and a plurality of electrical connection structures. The flexible buffer structure includes a flexible buffer material layer. The structural strengthening module, the electrical detection module and the flexible buffer structure are configured to cooperate with each other to form the chip electrical property detection device. The probe carrying substrate is disposed on the flexible buffer material layer, and the electrical detection structures are respectively disposed on the probe carrying substrate and electrically connected to the electrical connection structures.

In order to solve the above-mentioned problems, another one of the technical aspects adopted by the present disclosure is to provide a method of manufacturing a chip electrical property detection device, which includes: providing a structural strengthening module, in which the structural strengthening module includes a structural strengthening substrate; providing an electrical detection module, in which the electrical detection module includes a probe carrying substrate, a plurality of electrical detection structures and a plurality of electrical connection structures; providing a flexible buffer structure, in which the flexible buffer structure includes a flexible buffer material layer; and then cooperating the structural strengthening module, the electrical detection module and the flexible buffer structure with each other to form the chip electrical property detection device. The probe carrying substrate is disposed on the flexible buffer material layer, and the electrical detection structures are respectively disposed on the probe carrying substrate and electrically connected to the electrical connection structures.

Therefore, in the chip electrical property detection device provided by the present disclosure, by virtue of “the structural strengthening module including a structural strengthening substrate,” “the electrical detection module including a probe carrying substrate, a plurality of electrical detection structures and a plurality of electrical connection structures,” “the flexible buffer structure including a flexible buffer material layer,” “the structural strengthening module, the electrical detection module and the flexible buffer structure being configured to cooperate with each other to form the chip electrical property detection device,” “the probe carrying substrate being disposed on the flexible buffer material layer” and “the electrical detection structures being respectively disposed on the probe carrying substrate and electrically connected to the electrical connection structures,” the probe carrying substrate can be configured to be allowed to be slightly adjusted through the flexible buffer material layer, thereby allowing each of the electrical detection structures to be configured to be slightly adjusted following the probe carrying substrate.

Furthermore, in the method of manufacturing the chip electrical property detection device provided by the present disclosure, by virtue of “providing a structural strengthening module that includes a structural strengthening substrate,” “providing an electrical detection module that includes a probe carrying substrate, a plurality of electrical detection structures and a plurality of electrical connection structures,” “providing a flexible buffer structure that includes a flexible buffer material layer,” “cooperating the structural strengthening module, the electrical detection module and the flexible buffer structure with each other to form the chip electrical property detection device,” “the probe carrying substrate being disposed on the flexible buffer material layer” and “the electrical detection structures being respectively disposed on the probe carrying substrate and electrically connected to the electrical connection structures,” the probe carrying substrate can be configured to be allowed to be slightly adjusted through the flexible buffer material layer, thereby allowing each of the electrical detection structures to be configured to be slightly adjusted following the probe carrying substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a chip electrical property detection device according to a first embodiment of the present disclosure;

FIG. 2 is a schematic exploded view of a circuit control module, an electrical detection module and a flexible conductive structure of the chip electrical property detection device provided by the first embodiment of the present disclosure;

FIG. 3 is a schematic view of the mutual cooperation structure between the circuit control module, the electrical detection module and the flexible conductive structure of the chip electrical property detection device provided by the first embodiment of the present disclosure (before separating the movable carrying substrates from each other);

FIG. 4 is a schematic view of the mutual cooperation structure between the circuit control module, the electrical detection module and the flexible conductive structure of the chip electrical property detection device provided by the first embodiment of the present disclosure (after separating the movable carrying substrates from each other);

FIG. 5 is a schematic view of the chip electrical property detection device configured to be applied to detect multiple chips to be detected according to the first embodiment of the present disclosure (before downward pressing the chip electrical property detection device to detect the multiple chips to be detected through a downward pressure provided by a flexible pressing device);

FIG. 6 is a schematic view of the chip electrical property detection device configured to be applied to detect the multiple chips to be detected according to the first embodiment of the present disclosure (when downward pressing the chip electrical property detection device to detect the multiple chips to be detected through the downward pressure provided by the flexible pressing device);

FIG. 7 is a schematic view of the mutual cooperation structure between the circuit control module, the electrical detection module and the flexible conductive structure of the chip electrical property detection device provided by a second embodiment of the present disclosure;

FIG. 8 is a schematic view of the mutual cooperation structure between the circuit control module, the electrical detection module and the flexible conductive structure of the chip electrical property detection device provided by a third embodiment of the present disclosure;

FIG. 9 is a flowchart of a method for manufacturing a chip electrical property detection device according to a fourth embodiment of the present disclosure;

FIG. 10 is a schematic exploded view of a circuit control module, an electrical detection module and a flexible conductive structure of the chip electrical property detection device provided by the fourth embodiment of the present disclosure;

FIG. 11 is a schematic view of the mutual cooperation structure between the circuit control module, the electrical detection module and the flexible conductive structure of the chip electrical property detection device provided by the fourth embodiment of the present disclosure;

FIG. 12 is a schematic view of the chip electrical property detection device configured to be applied to detect multiple chips to be detected according to the fourth embodiment of the present disclosure (before downward pressing the chip electrical property detection device to detect the multiple chips to be detected through a downward pressure provided by a flexible pressing device);

FIG. 13 is a schematic view of the chip electrical property detection device configured to be applied to detect the multiple chips to be detected according to the fourth embodiment of the present disclosure (when downward pressing the chip electrical property detection device to detect the multiple chips to be detected through the downward pressure provided by the flexible pressing device); and

FIG. 14 is a schematic view of the mutual cooperation structure between the circuit control module, the electrical detection module and the flexible conductive structure of the chip electrical property detection device provided by a fifth embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

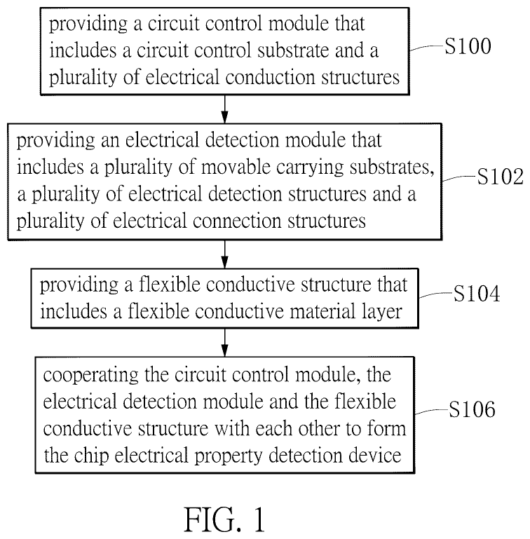

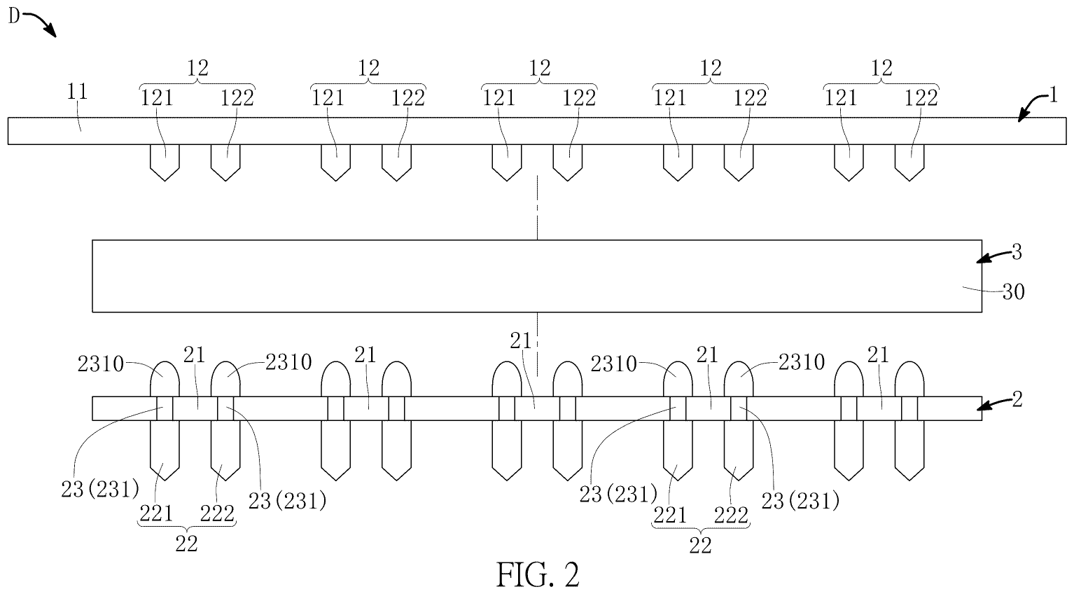

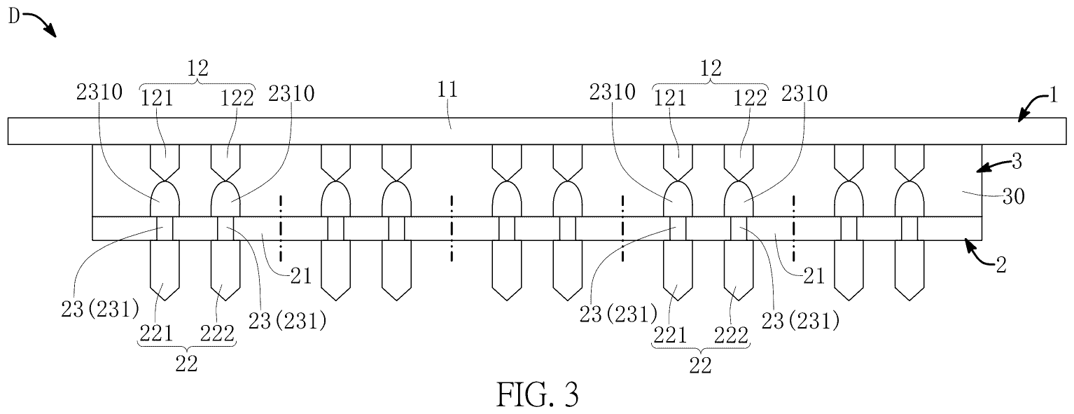

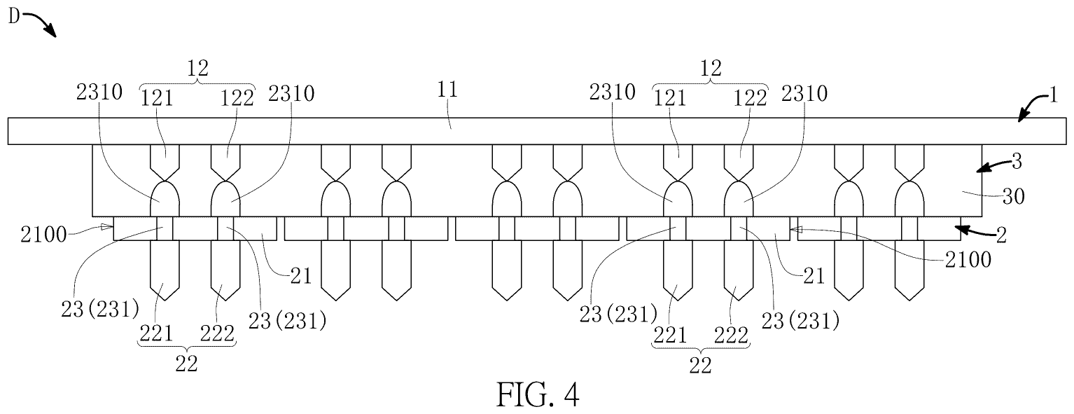

Referring to FIG. 1 to FIG. 6, a first embodiment of the present disclosure provides a method of manufacturing a chip electrical property detection device D, which may at least include: firstly, referring to FIG. 1 and FIG. 2, providing a circuit control module 1, in which the circuit control module 1 includes a circuit control substrate 11 and a plurality of electrical conduction structures 12 (step S100); next, referring to FIG. 1 and FIG. 3, providing an electrical detection module 2, in which the electrical detection module 2 includes a plurality of movable carrying substrates 21 (before the movable carrying substrates 21 can be separated from each other), a plurality of electrical detection structures 22 and a plurality of electrical connection structures 23 (step S1020); next, referring to FIG. 1 and FIG. 2, providing a flexible conductive structure 3, in which the flexible conductive structure 3 at least includes a flexible conductive material layer 30 (step S104); then, referring to FIG. 1, FIG. 2 and FIG. 3, cooperating (or matching) the circuit control module 1, the electrical detection module 2 and the flexible conductive structure 3 with each other (such as electrically bonding the circuit control module 1 on the electrical detection module 2 through the flexible conductive structure 3) to form the chip electrical property detection device D (step S106). It should be noted that referring to FIG. 3 and FIG. 4, in the step S106, the electrical detection module 2 can perform a cutting step (or a material removal step) along the multiple cutting lines (i.e., multiple imaginary lines as shown in FIG. 3), so that the movable carrying substrates 21 can be separated from each other and can move independently. For example, when the movable carrying substrates 21 are separated from each other through the cutting step (or the material removal step), two adjacent ones of the movable carrying substrates 21 can be separated from each other by a predetermined distance, and an outer surrounding surface of each movable carrying substrate 21 can be a surrounding cutting surface 2100 (or a surrounding roughened surface) formed by cutting or removing material. However, the aforementioned details are disclosed for exemplary purposes only, and are not meant to limit the scope of the present disclosure.

Moreover, as shown in FIG. 2, the circuit control substrate 11 has a predetermined circuit layout (or a predetermined circuit pattern including multiple conductive vias, or a predetermined circuit trace including multiple conductive vias, or an LED lighting circuit including multiple scan lines and multiple data lines that can be manufactured by a semiconductor process), and the electrical conduction structures 12 (or the electrically conductive pins) can be disposed on the circuit control substrate 11 and electrically connected to the predetermined circuit layout of the circuit control substrate 11. For example, in one of the feasible embodiments, the predetermined circuit layout of the circuit control substrate 11 may include one or more bottom circuits (not shown) provided on the bottom side of the circuit control substrate 11, one or more top circuit (not shown) provided on the top side of the circuit control substrate 11, and one or more through circuits (or conductive vias, not shown) penetrating the circuit control substrate 11, and the circuit control substrate 11 can be configured as a first silicon wafer substrate or any kind of rigid carrier substrate. In addition, each electrical conduction structure 12 of the circuit control module 1 may at least include a first conduction element 121 (or a first conductive pin) and a second conduction element 122 (or a second conductive pin) adjacent to each other, the first conduction element 121 and the second conduction element 122 of each electrical conduction structure 12 can be electrically connected to the bottom circuit (not shown) or the through circuit (not shown) of the circuit control substrate 11, and the first conduction element 121 and the second conduction element 122 of each electrical conduction structure 12 can extend downward from a bottom side of the circuit control substrate 11. However, the aforementioned details are disclosed for exemplary purposes only, and are not meant to limit the scope of the present disclosure.

More particularly, referring to FIG. 2 and FIG. 3, the flexible conductive structure 3 can be electrically connected between the circuit control module 1 and the electrical detection module 2, so that the electrical detection module 2 can be electrically connected to the circuit control module 1 through the flexible conductive structure 3. For example, the flexible conductive material layer 30 can be configured as any kind of conductive rubber, any kind of conductive polymer, any kind of anisotropic conductive paste (ACP), or can be configured as any kind of anisotropic conductive film (ACF), or can use any kind of soft conductive material or flexible conductive material, or any conductive material that can provide an elastic effect or a flexible effect. It should be noted that the interior of the conductive rubber includes a plurality of embedded conductive gold wires (or a plurality of embedded conductive materials) respectively corresponding to the plurality of electrical conduction structures 12 (including a plurality of first conduction elements 121 and a plurality of second conduction elements 122) or the plurality of top conductive elements 2310. However, the aforementioned details are disclosed for exemplary purposes only, and are not meant to limit the scope of the present disclosure.

More particularly, referring to FIG. 3 and FIG. 4, the movable carrying substrates 21 can be separated from each other and disposed on the flexible conductive material layer 30 by cutting or removing material (or by a cutting step or a material removal step), the electrical detection structures 22 can be respectively disposed on the movable carrying substrates 21 and electrically connected to the electrical connection structures 23, and the electrical connection structures 23 can respectively pass through the movable carrying substrates 21 and can be respectively and electrically connected to the electrical conduction structures 12 through the flexible conductive material layer 30. For example, in one of the feasible embodiments, the movable carrying substrate 21 can be configured as a second silicon wafer substrate or any kind of relatively rigid carrier substrate, each electrical detection structure 22 may at least include a first electrical detection probe 221 (or a first power supply probe, or a first electrical contact probe, or a P-pole contact probe) and a second electrical detection probe 222 (or a second power supply probe, or a second electrical contact probe, or an N-pole contact probe), and each electrical connection structure 23 may at least include two conductive through layers 231 or two conductive penetrating layers (such as two solid conductive pillars, two hollow conductive vias or two through-silicon vias (TSV)) that can pass through the movable carrying substrate 21, each conductive through layer 231 has a top conductive element 2310 (or a top conductive pin) disposed on a top side thereof, and a bottom side of each conductive through layer 231 can be in electrical contact with the corresponding electrical detection structure 22 (such as one of the first electrical detection probe 221 and the second electrical detection probe 222). Therefore, as shown in FIG. 4, when the circuit control module 1, the electrical detection module 2 and the flexible conductive structure 3 cooperate with each other to form the chip electrical property detection device D, the bottom side of each conductive through layer 231 can electrically contact the corresponding electrical detection structure 22, so that the first electrical detection probe 221 can be electrically connected to the circuit control module 1 through a corresponding one of the conductive through layers 231, the flexible conductive material layer 30 and a corresponding one of the first conduction elements 121 in sequence, and the second electrical detection probe 222 can be electrically connected to the circuit control module 1 through another corresponding one of the conductive through layers 231, the flexible conductive material layer 30 and another corresponding one of the second conduction elements 122 in sequence. For example, in one of the feasible embodiments, the first electrical detection probe 221 of the electrical detection structure 22 and the conductive through layer 231 of the electrical connection structure 23 that are electrically connected to each other can be an integrally formed conductive structure or non-integrated conductive structure, and the second electrical detection probe 222 of the electrical detection structure 22 and the conductive through layer 231 of the electrical connection structure 23 that are electrically connected to each other can be an integrally formed conductive structure or non-integrated conductive structure. However, the aforementioned details are disclosed for exemplary purposes only, and are not meant to limit the scope of the present disclosure.

More particularly, referring to FIG. 3 and FIG. 4, in one of the feasible embodiments, the first conduction element 121 and the second conduction element 122 of each electrical conduction structure 12 can respectively in direct electrical contact with the two correspond top conductive elements 2310 (as shown in FIG. 4), or the first conduction element 121 and the second conduction element 122 of each electrical conduction structure 12 can respectively separate from the two corresponding top conductive elements 2310 by a predetermined distance. It should be noted that, when the first conduction element 121 and the second conduction element 122 of each electrical conduction structure 12 are respectively separate from the two corresponding top conductive elements 2310 by a predetermined distance, the first conduction element 121 and the second conduction element 122 of each electrical conduction structure 12 can be electrically connected to the two corresponding top conductive elements 2310 respectively through the flexible conductive material layer 30. However, the aforementioned details are disclosed for exemplary purposes only, and are not meant to limit the scope of the present disclosure.

It should be noted that as shown in FIG. 4, the movable carrying substrates 21 can be separately disposed on a bottom side of the flexible conductive material layer 30 by cutting or removing material, so that each movable carrying substrate 21 can be configured to be allowed to be slightly adjusted through the flexible load-bearing of the flexible conductive material layer 30 (that is to say, the position of each movable carrying substrate 21 can be allowed to be slightly adjusted through the soft carrier or flexible carrier of the flexible conductive material layer 30, the flexible conductive material layer 30 can be used as a flexible carrier shared by the multiple movable carrying substrates 21, and each movable carrying substrate 21 can be slightly adjusted or moved in a horizontal direction, a vertical direction or a tilt direction), thereby allowing each electrical detection structure 22 to be configured to be slightly adjusted following the corresponding movable carrying substrate 21 (that is to say, each electrical detection structure 22 can be configured to be in a state that the position can be slightly adjusted corresponding to the corresponding movable carrying substrate 21). For example, the first electrical detection probe 221 and the second electrical detection probe 222 of each electrical detection structure 22 can be slightly adjusted or moved in the horizontal direction, the vertical direction or the tilt direction at the same time). However, the aforementioned details are disclosed for exemplary purposes only, and are not meant to limit the scope of the present disclosure.

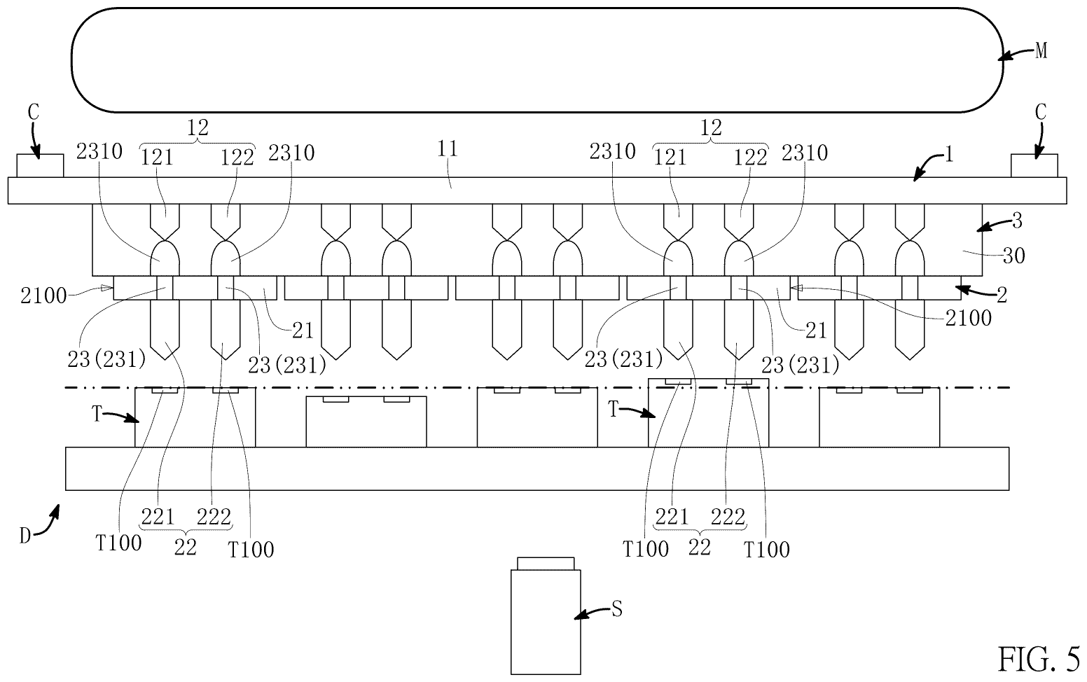

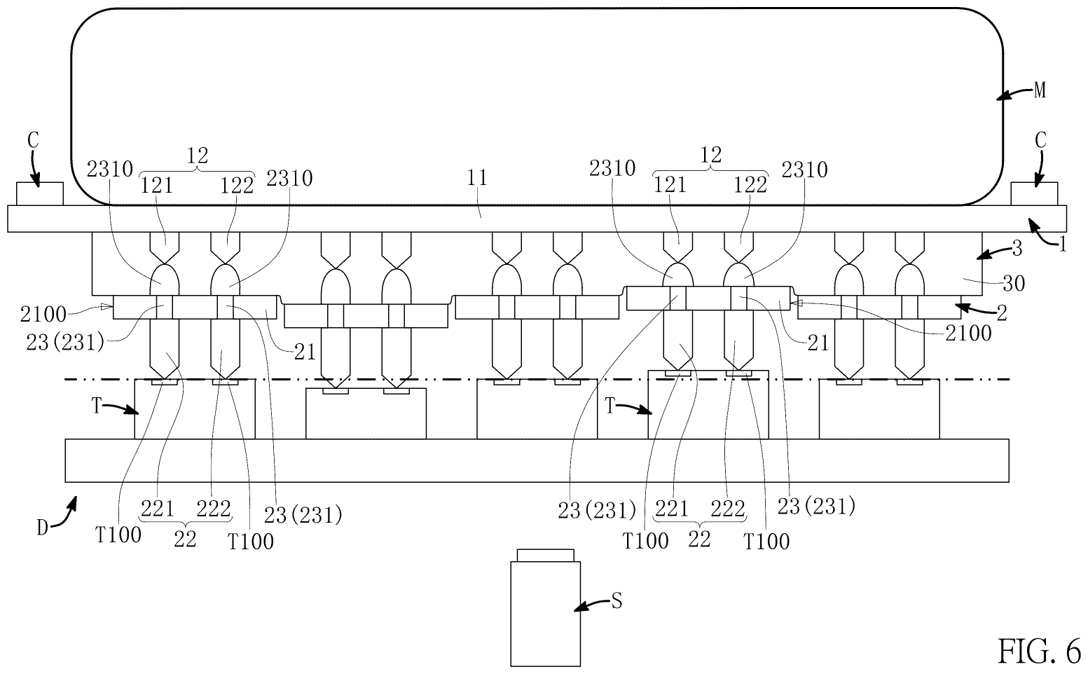

For example, referring to FIG. 5 and FIG. 6, when the chip electrical property detection device D (such as an LED lighting and testing instrument) can be configured to detect a plurality of chips T to be detected (such as multiple micro LED dies or multiple mini LED dies disposed on a gallium arsenide epitaxial wafer, or any kind of unpackaged light-emitting die), the chip electrical property detection device D can be configured to be moved downward through a downward pressure provided by a flexible pressing device (such as an air bag or any kind of flexible pressing plate as shown in FIG. 6), so that the first electrical detection probe 221 and the second electrical detection probe 222 of each electrical detection structure 22 can reliably electrically contact two conductive pads T100 of a corresponding one of the chips T to be detected respectively, or the first electrical detection probe 221 and the second electrical detection probe 222 of each electrical detection structure 22 can provide a fixed current (or a fixed voltage) to the two conductive pads T100 of the corresponding chip T to be detected. It should be noted that as shown in FIG. 6, even when the plurality of chips T to be detected are not in a completely flat state such that the plurality of conductive pads T100 of the plurality of chips T to be detected cannot be located on the same horizontal plane (as shown by the imaginary line in FIG. 6) (or when the entire circuit substrate used to carry the multiple chips T is warped to form a warpage circuit substrate), each electrical detection structure 22 can be configured to allow its position to be slightly adjusted following the corresponding movable carrying substrate 21, so that the first electrical detection probe 221 and the second electrical detection probe 222 of each electrical detection structure 22 can reliably electrically contact the two conductive pads T100 of the corresponding chip T to be detected, or the first electrical detection probe 221 and the second electrical detection probe 222 of each electrical detection structure 22 can reliably provide a fixed current (or a fixed voltage) to the two conductive pads T100 of the corresponding chip T to be detected. Therefore, the multiple chips T to be detected can generate detection light sources through the electrical supply of the multiple electrical detection structures 22 at the same time, thereby providing the detection light source to the optical detection device S to facilitate relevant optical detection (or LED lighting test) of multiple chips T to be detected. However, the aforementioned details are disclosed for exemplary purposes only, and are not meant to limit the scope of the present disclosure.

It should be noted that, for example, as shown in FIG. 5 or FIG. 6, the circuit control substrate 11 of the circuit control module 1 can be configured to carry a plurality of functional chips C (such as control chips, memory chips or any kind of semiconductor chips), and each functional chip C can be electrically connected to a corresponding one of the electrical detection structures 22 through a corresponding one of the electrical conduction structures 12, the flexible conductive material layer 30 and a corresponding one of the electrical connection structures 23. However, the aforementioned details are disclosed for exemplary purposes only, and are not meant to limit the scope of the present disclosure.

More particularly, referring to FIG. 4, FIG. 5 and FIG. 6, the first embodiment of the present disclosure further provides a chip electrical property detection device D (or a chip electrical status testing device), which includes a circuit control module 1, an electrical detection module 2 and a flexible conductive structure 3, and the circuit control module 1, the electrical detection module 2 and the flexible conductive structure 3 can be configured to cooperate with each other in any way to form the chip electrical property detection device D. Moreover, the circuit control module 1 includes a circuit control substrate 11 and a plurality of electrical conduction structures 12, in which the circuit control substrate 11 has a predetermined circuit layout, and the electrical conduction structures 12 can be disposed on the circuit control substrate 11 and electrically connected to the predetermined circuit layout of the circuit control substrate 11. In addition, the electrical detection module 2 includes a plurality of movable carrying substrates 21, a plurality of electrical detection structures 22 and a plurality of electrical connection structures 23, and the flexible conductive structure 3 at least includes a flexible conductive material layer 30. More particularly, the flexible conductive structure 3 can be electrically connected between the circuit control module 1 and the electrical detection module 2, and the electrical detection module 2 can be electrically connected to the circuit control module 1 through the flexible conductive structure 3. In addition, the movable carrying substrates 21 can be separated from each other and disposed on the flexible conductive material layer 30, the electrical detection structures 22 can be respectively disposed on the movable carrying substrates 21 and electrically connected to the electrical connection structures 23, and the electrical connection structures 23 can respectively pass through the movable carrying substrates 21 and can be respectively and electrically connected to the electrical conduction structures 12 through the flexible conductive material layer 30. For example, the movable carrying substrates 21 can be separately disposed on a bottom side of the flexible conductive material layer 30 by cutting or removing material, so that each movable carrying substrate 21 can be configured to be allowed to be slightly adjusted through the flexible load-bearing of the flexible conductive material layer 30, thereby allowing each electrical detection structure 22 to be configured to be slightly adjusted following the corresponding movable carrying substrate 21.

Furthermore, as shown in FIG. 6, each electrical detection structure 22 can be configured to be slightly adjusted following the corresponding movable carrying substrate 21, so that the first electrical detection probe 221 and the second electrical detection probe 222 of each electrical detection structure 22 can reliably electrically contact two conductive pads T100 of a corresponding one of the chips T to be detected respectively, or the first electrical detection probe 221 and the second electrical detection probe 222 of each electrical detection structure 22 can provide a fixed current (or a fixed voltage) to the two conductive pads T100 of the corresponding chip T to be detected. It should be noted that when each electrical detection structure 22 can be configured to allow the corresponding movable carrying substrate 21 to be in a state that allows the position of each electrical detection structure 22 to be slightly adjusted, the electrical detection structures 22 can provide a uniform pressing force for the multiple chips T to be detected through the flexible conductive material layer 30, thereby avoiding damage to the multiple chips T to be detected due to the contact electrical detection method (that is to say, thereby avoiding the multiple chips T to be detected from being broken due to the contact electrical detection method). However, the aforementioned details are disclosed for exemplary purposes only, and are not meant to limit the scope of the present disclosure.

### Second Embodiment

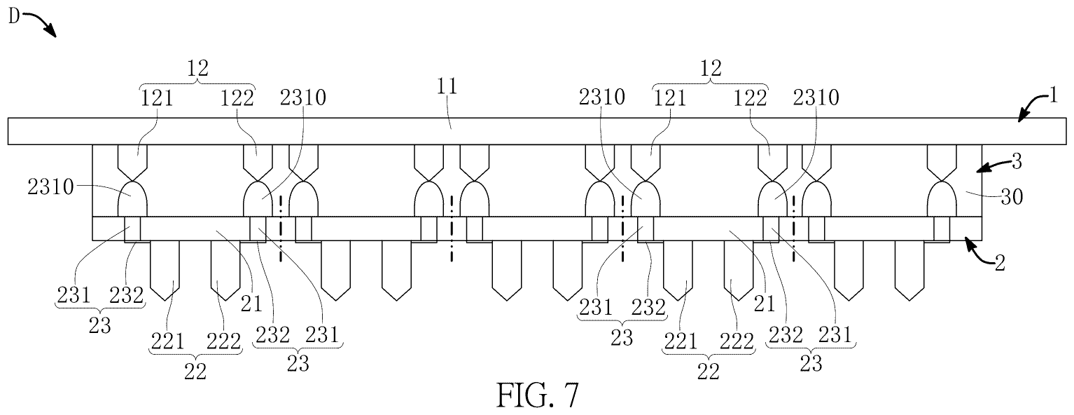

Referring to FIG. 7, a second embodiment of the present disclosure provides a chip electrical property detection device D, which includes a circuit control module 1, an electrical detection module 2 and a flexible conductive structure 3. Comparing FIG. 7 with FIG. 3, the main difference between the second embodiment and the first embodiment is as follows: in the second embodiment, each electrical connection structure 23 may at least include two conductive through layers 231 (such as two solid conductive pillars, two hollow conductive vias or two through-silicon vias (TSV)) and two conductive connection layers 232 (such as two conductive circuit layers). More particularly, the two conductive through layers 231 can pass through a corresponding one of the movable carrying substrates 21, and the two conductive connection layers 232 can be disposed on a bottom side of the corresponding movable carrying substrate 21, each conductive through layer 231 has a top conductive element 2310 (or a top conductive pin) disposed on a top side thereof, and a bottom side of each conductive through layer 231 can directly and electrically contact the corresponding conductive connection layer 232.

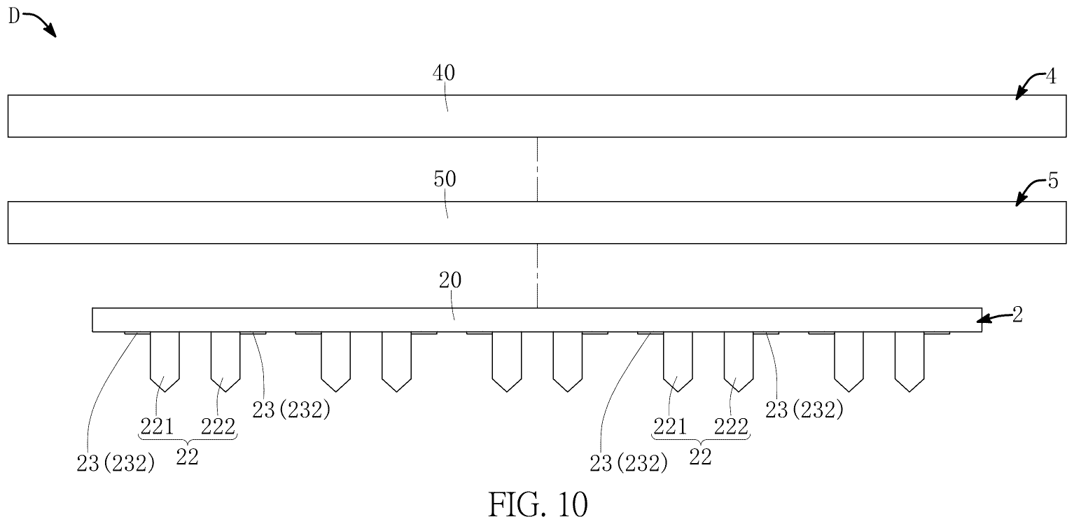

More particularly, as shown in FIG. 10, when the circuit control module 1, the electrical detection module 2 and the flexible conductive structure 3 cooperate with each other to form the chip electrical property detection device D, the first electrical detection probe 221 can be electrically connected to the circuit control module 1 through a corresponding one of the conductive connection layers 232, a corresponding one of the conductive through layers 231, the flexible conductive material layer 30 and a corresponding one of the first conduction elements 121 in sequence, and the second electrical detection probe 222 can be electrically connected to the circuit control module 1 through another corresponding one of the conductive connection layers 232, another corresponding one of the conductive through layers 231, the flexible conductive material layer 30 and another corresponding one of the second conduction elements 122 in sequence. However, the aforementioned details are disclosed for exemplary purposes only, and are not meant to limit the scope of the present disclosure.

Therefore, the same as the first embodiment, as shown in FIG. 6, the movable carrying substrates 21 can be separately disposed on a bottom side of the flexible conductive material layer 30 by cutting or removing material, so that each movable carrying substrate 21 can be configured to be allowed to be slightly adjusted through the flexible load-bearing of the flexible conductive material layer 30, thereby allowing each electrical detection structure 22 to be configured to be slightly adjusted following the corresponding movable carrying substrate 21. Furthermore, each electrical detection structure 22 can be configured to be slightly adjusted following the corresponding movable carrying substrate 21, so that the first electrical detection probe 221 and the second electrical detection probe 222 of each electrical detection structure 22 can reliably electrically contact two conductive pads (not shown) of a corresponding one of the chips (not shown) to be detected respectively.

### Third Embodiment

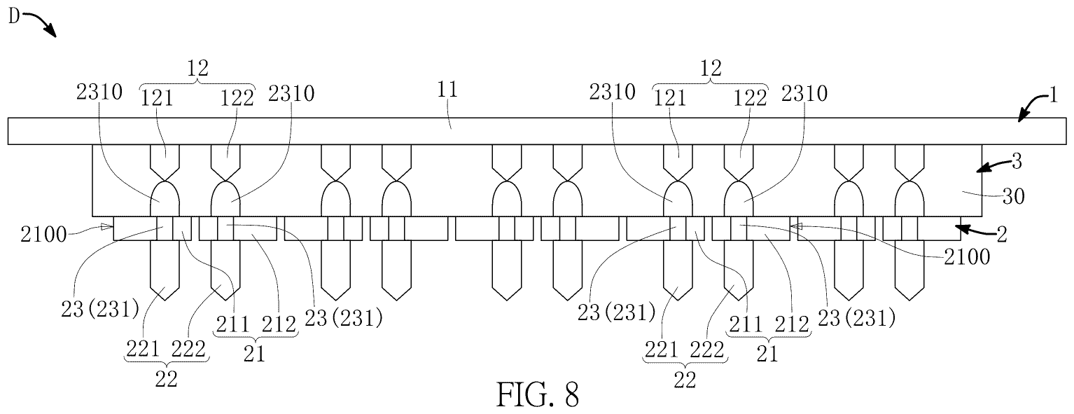

Referring to FIG. 8, a third embodiment of the present disclosure provides a chip electrical property detection device D, which includes a circuit control module 1, an electrical detection module 2 and a flexible conductive structure 3. Comparing FIG. 8 with FIG. 4, the main difference between the third embodiment and the first embodiment is as follows: in the third embodiment, each movable carrying substrate 21 further includes a first movable carrying plate 211 (in which the outer surrounding surface of the first movable carrying plate 211 may be a surrounding cut surface or a surrounding roughened surface formed by cutting or material removal) and a second movable carrying plate 212 (in which the outer surrounding surface of the second movable carrying plate 212 may be a surrounding cut surface or a surrounding roughened surface formed by cutting or material removal) that can be separated from each other by cutting or removing material (or by a cutting step or a material removal step), and the first electrical detection probe 221 and the second electrical detection probe 222 of each electrical detection structure 22 can be respectively disposed on the first movable carrying plate 211 and the second movable carrying plate 212 of the corresponding movable carrying substrate 21.

Therefore, as shown in FIG. 8, the first movable carrying plate 211 and the second movable carrying plate 212 of the movable carrying substrates 21 can be separately disposed on a bottom side of the flexible conductive material layer 30, so that the first movable carrying plate 211 and the second movable carrying plate 212 of each movable carrying substrate 21 can be configured to be allowed to be slightly adjusted through the flexible load-bearing of the flexible conductive material layer 30, thereby allowing the first electrical detection probe 221 and the second electrical detection probe 222 of each electrical detection structure 22 to be respectively configured to be slightly adjusted following the first movable carrying plate 211 and the second movable carrying plate 212 of the corresponding movable carrying substrate 21. Furthermore, the first electrical detection probe 221 and the second electrical detection probe 222 of each electrical detection structure 22 can be respectively configured to be slightly adjusted following the first movable carrying plate 211 and the second movable carrying plate 212 of the corresponding movable carrying substrate 21, so that the first electrical detection probe 221 and the second electrical detection probe 222 of each electrical detection structure 22 can reliably electrically contact two conductive pads (not shown) of a corresponding one of the chips (not shown) to be detected respectively.

### Fourth Embodiment

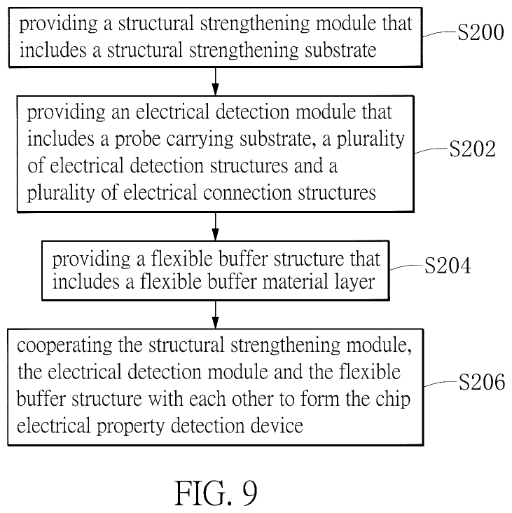

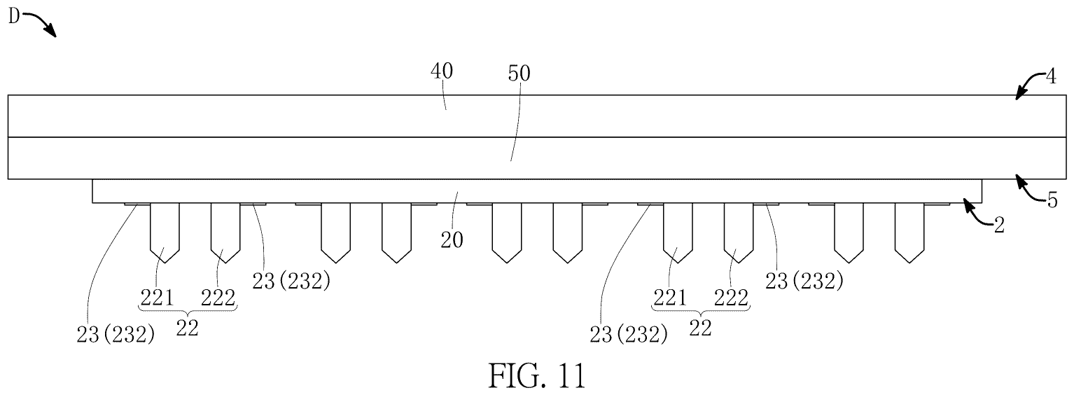

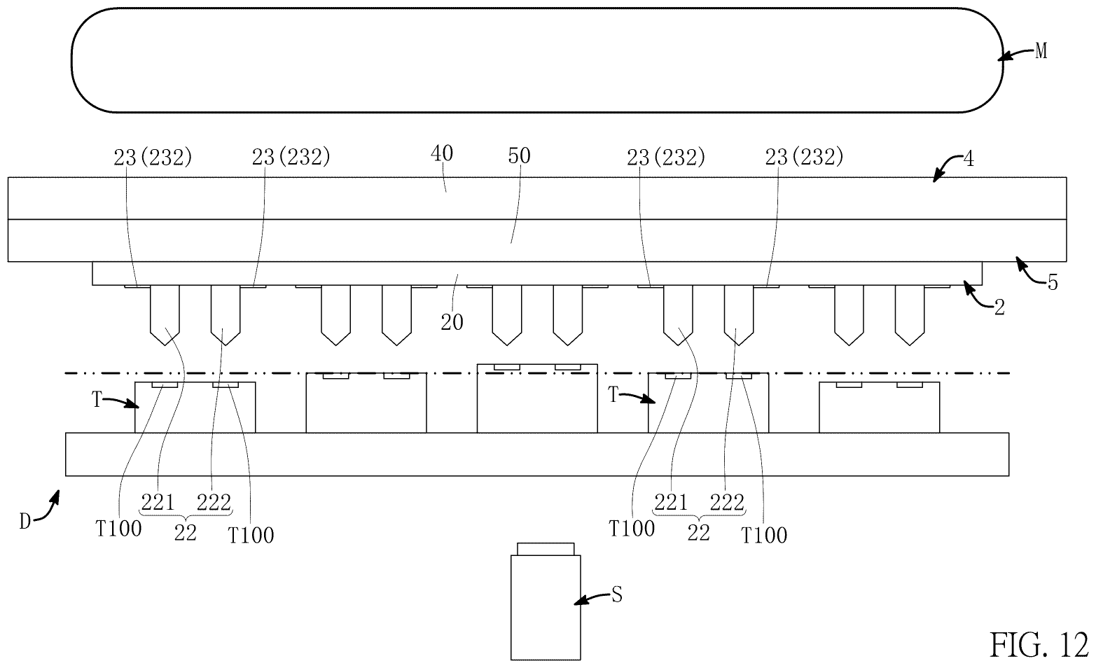

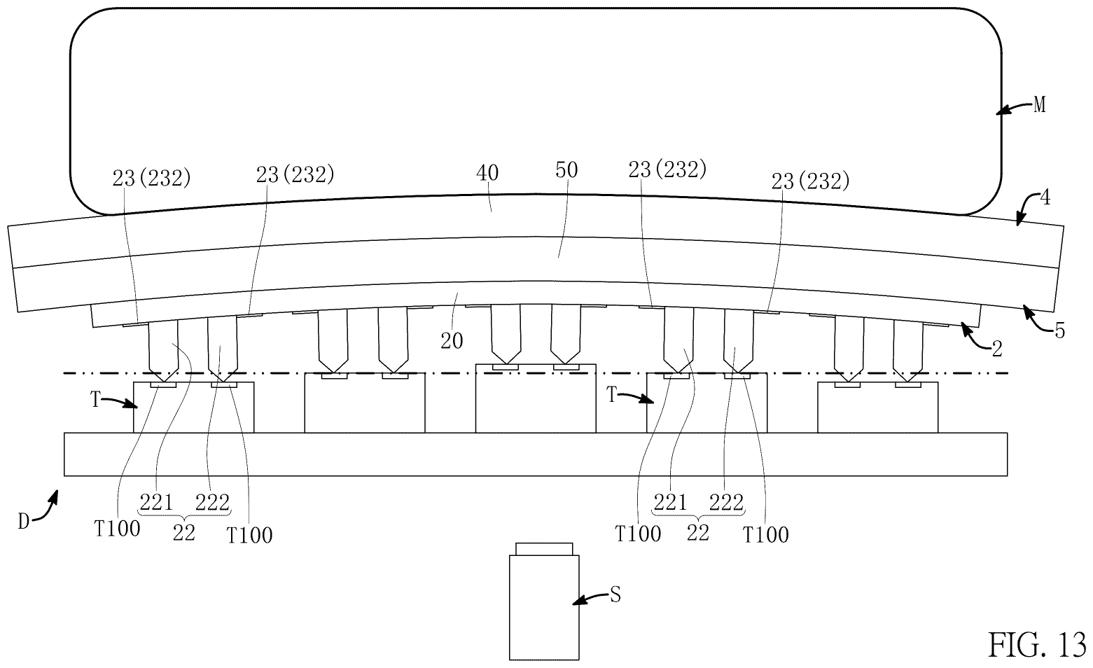

Referring to FIG. 9 to FIG. 13, a fourth embodiment of the present disclosure provides a method of manufacturing a chip electrical property detection device D, which includes: firstly, referring to FIG. 9 and FIG. 10, providing a structural strengthening module 4, in which the structural strengthening module 4 at least includes a structural strengthening substrate 40 (step S200); next, referring to FIG. 9 and FIG. 10, providing an electrical detection module 2, in which the electrical detection module 2 at least includes a probe carrying substrate 20, a plurality of electrical detection structures 22 and a plurality of electrical connection structures 23 (step S202); next, referring to FIG. 9 and FIG. 10, providing a flexible buffer structure 5, in which the flexible buffer structure 5 at least includes a flexible buffer material layer 50 (step S204); next, referring to FIG. 9, FIG. 10 and FIG. 11, cooperating (or matching) the structural strengthening module 4, the electrical detection module 2 and the flexible buffer structure 5 with each other (such as placing the flexible buffer structure 5 between the structural strengthening module 4 and the electrical detection module 2) to form the chip electrical property detection device D (step S206). More particularly, the probe carrying substrate 20 can be disposed on the flexible buffer material layer 50, and the electrical detection structures 22 can be respectively disposed on the probe carrying substrate 20 and electrically connected to the electrical connection structures 23. In addition, each of the electrical detection structures 22 includes a first electrical detection probe 221 (or a first power supply probe, or a first electrical contact probe, or a P-pole contact probe) and a second electrical detection probe 222 (or a second power supply probe, or a second electrical contact probe, or an N-pole contact probe). Therefore, referring to FIG. 12 and FIG. 13, the probe carrying substrate 20 can be configured to be allowed to be slightly adjusted through the flexible load-bearing of the flexible buffer material layer 50 (that is to say, the position of the probe carrying substrate 20 can be allowed to be slightly adjusted through the soft carrier or flexible carrier of the flexible buffer material layer 50), thereby allowing the first electrical detection probe 221 and the second electrical detection probe 222 of each electrical detection structure 22 to be configured to be slightly adjusted following the probe carrying substrate 20 (that is to say, the first electrical detection probe 221 and the second electrical detection probe 222 of each electrical detection structure 22 can be configured to be in a state that the position can be slightly adjusted corresponding to the probe carrying substrate 20).

For example, in one of the feasible embodiments, the structural strengthening substrate 40 can be configured as a first silicon wafer substrate or any kind of relatively rigid carrier substrate, and the probe carrying substrate 20 can be configured as a second silicon wafer substrate or any kind of relatively rigid carrier substrate. In addition, the flexible buffer material layer 50 (or an elastic material layer, or a flexible material layer) can be configured as a prefabricated polymer material layer (or any kind of polymer film material), and the prefabricated polymer material layer can be a silicone layer or an epoxy layer. It should be noted that when the structural strengthening substrate 40 of the structural strengthening module 4 is used as a circuit substrate according to different requirements, the circuit substrate can be configured to carry a plurality of functional chips C (such as multiple control chips, multiple memory chips or any kind of multiple semiconductor chips). However, the aforementioned details are disclosed for exemplary purposes only, and are not meant to limit the scope of the present disclosure.

For example, referring to FIG. 12 and FIG. 13, when the chip electrical property detection device D (such as an LED lighting and testing instrument) can be configured to detect a plurality of chips T to be detected (such as multiple micro LED dies or multiple mini LED dies disposed on a gallium arsenide epitaxial wafer, or any kind of unpackaged light-emitting die), the chip electrical property detection device D can be configured to be moved downward through a downward pressure provided by a flexible pressing device (such as an air bag or any kind of flexible pressing plate as shown in FIG. 13), so that the first electrical detection probe 221 and the second electrical detection probe 222 of each electrical detection structure 22 can reliably electrically contact two conductive pads T100 of a corresponding one of the chips T to be detected respectively, or the first electrical detection probe 221 and the second electrical detection probe 222 of each electrical detection structure 22 can provide a fixed current (or a fixed voltage) to the two conductive pads T100 of the corresponding chip T to be detected. It should be noted that as shown in FIG. 13, even when the plurality of chips T to be detected are not in a completely flat state such that the plurality of conductive pads T100 of the plurality of chips T to be detected cannot be located on the same horizontal plane (as shown by the imaginary line in FIG. 13) (or when the entire circuit substrate used to carry the multiple chips T is warped to form a warpage circuit substrate), each electrical detection structure 22 can be configured to allow its position to be slightly adjusted following the flexible buffer material layer 50, so that the first electrical detection probe 221 and the second electrical detection probe 222 of each electrical detection structure 22 can reliably electrically contact the two conductive pads T100 of the corresponding chip T to be detected, or the first electrical detection probe 221 and the second electrical detection probe 222 of each electrical detection structure 22 can reliably provide a fixed current (or a fixed voltage) to the two conductive pads T100 of the corresponding chip T to be detected. Therefore, the multiple chips T to be detected can generate detection light sources through the electrical supply of the multiple electrical detection structures 22 at the same time, thereby providing the detection light source to the optical detection device S to facilitate relevant optical detection (or LED lighting test) of multiple chips T to be detected. More particularly, when each electrical detection structure 22 can be configured to allow the flexible buffer material layer 50 to be in a state that allows the position of each electrical detection structure 22 to be slightly adjusted, the electrical detection structures 22 can provide a uniform pressing force for the multiple chips T to be detected through the flexible buffer material layer 50, thereby avoiding damage to the multiple chips T to be detected due to the contact electrical detection method (that is to say, thereby avoiding the multiple chips T to be detected from being broken due to the contact electrical detection method). However, the aforementioned details are disclosed for exemplary purposes only, and are not meant to limit the scope of the present disclosure.

More particularly, referring to FIG. 11, FIG. 12 and FIG. 13, the fourth embodiment of the present disclosure provides a chip electrical property detection device D, which includes a structural strengthening module 4 (or a structural reinforcement module 4), an electrical detection module 2 and a flexible buffer structure 5, and the structural strengthening module 4, the electrical detection module 2 and the flexible buffer structure 5 can be configured to cooperate with each other in any way to form the chip electrical property detection device D. Moreover, the structural strengthening module 4 includes a structural strengthening substrate 40 (or a structural reinforcement substrate 40), the electrical detection module 2 includes a probe carrying substrate 20, a plurality of electrical detection structures 22 and a plurality of electrical connection structures 23, and the flexible buffer structure 5 includes a flexible buffer material layer 50. In addition, the probe carrying substrate 20 is disposed on the flexible buffer material layer 50, and the electrical detection structures 22 are respectively disposed on the probe carrying substrate 20 and electrically connected to the electrical connection structures 23. For example, each electrical detection structure 22 can be configured to be slightly adjusted following the flexible buffer material layer 50, so that the first electrical detection probe 221 and the second electrical detection probe 222 of each electrical detection structure 22 can reliably electrically contact two conductive pads T100 of a corresponding one of the chips T to be detected respectively. Therefore, the multiple chips T to be detected can generate detection light sources through the electrical supply of the multiple electrical detection structures 22 at the same time, thereby providing the detection light source to the optical detection device S to facilitate relevant optical detection (or LED lighting test) of multiple chips T to be detected. However, the aforementioned details are disclosed for exemplary purposes only, and are not meant to limit the scope of the present disclosure.

### Fifth Embodiment

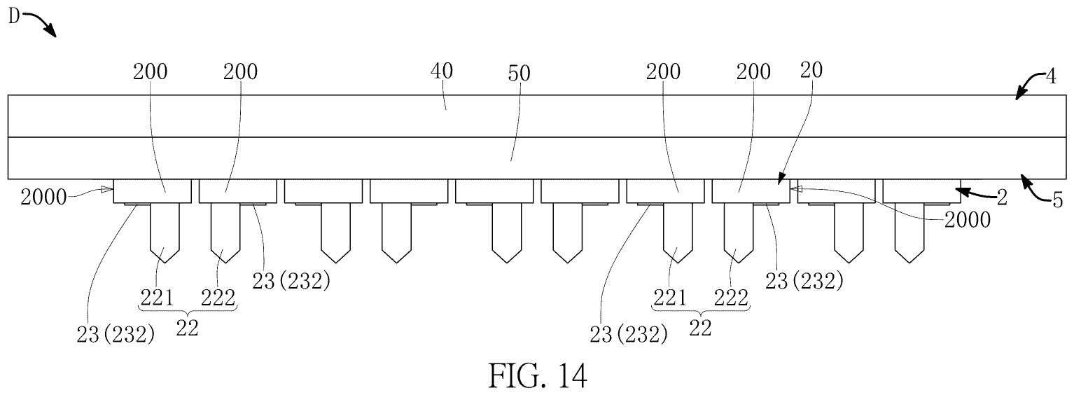

Referring to FIG. 14, a fifth embodiment of the present disclosure provides a chip electrical property detection device D, which includes a structural strengthening module 4, an electrical detection module 2 and a flexible buffer structure 5. Comparing FIG. 14 with FIG. 11, the main difference between the fifth embodiment and the fourth embodiment is as follows: in the fifth embodiment, the probe carrying substrate 20 further includes a plurality of movable carrying plates 200 that can be separated from each other by cutting or removing material (or by a cutting step or a material removal step), and the movable carrying plates 200 can be separately disposed on the flexible buffer material layer 50. More particularly, the first electrical detection probe 221 and the second electrical detection probe 222 of each electrical detection structure 22 can be respectively disposed on the two corresponding movable carrying plates 200 of the probe carrying substrate 20. In addition, every two adjacent movable carrying plates 200 are separate from each other by a predetermined distance, and an outer surrounding surface of each movable carrying plate 200 can be a surrounding cutting surface 2000 (or a surrounding roughened surface) formed by cutting or material removal. Therefore, the movable carrying plates 200 can be separately disposed on a bottom side of the flexible buffer material layer 50, so that each of the movable carrying plates 200 can be configured to be allowed to be slightly adjusted through the flexible buffer material layer 50 (that is to say, the position of each movable carrying plate 200 can be allowed to be slightly adjusted through the soft carrier or flexible carrier of the flexible buffer material layer 50), thereby allowing the first electrical detection probe 221 and the second electrical detection probe 222 of each electrical detection structure 22 to be configured to be slightly adjusted following the flexible buffer material layer 50 (that is to say, the first electrical detection probe 221 and the second electrical detection probe 222 of each electrical detection structure 22 can be configured to be in a state that the position can be slightly adjusted corresponding to the flexible buffer material layer 50).

### Beneficial Effects of the Embodiments

In conclusion, in the chip electrical property detection device D provided by the present disclosure, by virtue of “the circuit control module 1 including a circuit control substrate 11 and a plurality of electrical conduction structures 12,” “the electrical detection module 2 including a plurality of movable carrying substrates 21, a plurality of electrical detection structures 22 and a plurality of electrical connection structures 23,” “the flexible conductive structure 3 including a flexible conductive material layer 30,” “the circuit control module 1, the electrical detection module 2 and the flexible conductive structure 3 being configured to cooperate with each other to form the chip electrical property detection device D,” “the movable carrying substrates 21 being separate from each other and disposed on the flexible conductive structure 30,” “the electrical detection structures 22 being respectively disposed on the movable carrying substrates 21 and electrically connected to the electrical connection structures 23” and “the electrical connection structures 23 respectively passing through the movable carrying substrates 21 and respectively and electrically connecting to the electrical conduction structures 12 through the flexible conductive structure 30,” each movable carrying substrate 21 can be configured to be allowed to be slightly adjusted through the flexible load-bearing of the flexible conductive structure 30, thereby allowing each electrical detection structure 22 to be configured to be slightly adjusted following the corresponding movable carrying substrate 21.

Furthermore, in the method of manufacturing the chip electrical property detection device D provided by the present disclosure, by virtue of “providing a circuit control module 1, in which the circuit control module 1 includes a circuit control substrate 11 and a plurality of electrical conduction structures 12,” “providing an electrical detection module 2, in which the electrical detection module 2 includes a plurality of movable carrying substrates 21, a plurality of electrical detection structures 22 and a plurality of electrical connection structures 23,” “providing a flexible conductive structure 3, in which the flexible conductive structure 3 includes a flexible conductive material layer 30,” “cooperating the circuit control module 1, the electrical detection module 2 and the flexible conductive structure 3 with each other to form the chip electrical property detection device D,” “the movable carrying substrates 21 being separate from each other and disposed on the flexible conductive structure 30,” “the electrical detection structures 22 being respectively disposed on the movable carrying substrates 21 and electrically connected to the electrical connection structures 23” and “the electrical connection structures 23 respectively passing through the movable carrying substrates 21 and respectively and electrically connecting to the electrical conduction structures 12 through the flexible conductive structure 30,” each movable carrying substrate 21 can be configured to be allowed to be slightly adjusted through the flexible load-bearing of the flexible conductive structure 30, thereby allowing each electrical detection structure 22 to be configured to be slightly adjusted following the corresponding movable carrying substrate 21.

Furthermore, in the chip electrical property detection device D provided by the present disclosure, by virtue of “the structural strengthening module 4 including a structural strengthening substrate 40,” “the electrical detection module 2 including a probe carrying substrate 20, a plurality of electrical detection structures 22 and a plurality of electrical connection structures 23,” “the flexible buffer structure 5 including a flexible buffer material layer 50,” “the structural strengthening module 4, the electrical detection module 2 and the flexible buffer structure 5 being configured to cooperate with each other to form the chip electrical property detection device D,” “the probe carrying substrate 20 being disposed on the flexible buffer material layer 50” and “the electrical detection structures 22 being respectively disposed on the probe carrying substrate 20 and electrically connected to the electrical connection structures 23,” the probe carrying substrate 20 can be configured to be allowed to be slightly adjusted through the flexible buffer material layer 50, thereby allowing each of the electrical detection structures 22 to be configured to be slightly adjusted following the probe carrying substrate 20.

Furthermore, in the method of manufacturing the chip electrical property detection device D provided by the present disclosure, by virtue of “providing a structural strengthening module 4 that includes a structural strengthening substrate 40,” “providing an electrical detection module 2 that includes a probe carrying substrate 20, a plurality of electrical detection structures 22 and a plurality of electrical connection structures 23,” “providing a flexible buffer structure 5 that includes a flexible buffer material layer 50,” “cooperating the structural strengthening module 4, the electrical detection module 2 and the flexible buffer structure 5 with each other to form the chip electrical property detection device D,” “the probe carrying substrate 20 being disposed on the flexible buffer material layer 50” and “the electrical detection structures 22 being respectively disposed on the probe carrying substrate 20 and electrically connected to the electrical connection structures 23,” the probe carrying substrate 20 can be configured to be allowed to be slightly adjusted through the flexible buffer material layer 50, thereby allowing each of the electrical detection structures 22 to be configured to be slightly adjusted following the probe carrying substrate 20.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip electrical property detection device, comprising:
a structural strengthening module including a structural strengthening substrate;
an electrical detection module including a probe carrying substrate, a plurality of electrical detection structures and a plurality of electrical connection structures; and
a flexible buffer structure including a flexible buffer material layer;
wherein the structural strengthening module, the electrical detection module and the flexible buffer structure are configured to cooperate with each other to form the chip electrical property detection device;
wherein the probe carrying substrate is disposed on the flexible buffer material layer, and the electrical detection structures are respectively disposed on the probe carrying substrate and electrically connected to the electrical connection structures.

2. The chip electrical property detection device according to claim 1,
wherein each of the electrical detection structures includes a first electrical detection probe and a second electrical detection probe;
wherein the probe carrying substrate is configured to be allowed to be slightly adjusted through the flexible buffer material layer, thereby allowing each of the electrical detection structures to be configured to be slightly adjusted following the probe carrying substrate.

3. The chip electrical property detection device according to claim 1,
wherein the structural strengthening substrate of the structural strengthening module is configured to carry a plurality of functional chips;
wherein the flexible buffer material layer is configured as a prefabricated polymer material layer, and the prefabricated polymer material layer is a silicone layer or an epoxy layer;
wherein the structural strengthening substrate is configured as a first silicon wafer substrate, and the probe carrying substrate is configured as a second silicon wafer substrate.

4. The chip electrical property detection device according to claim 1,
wherein each of the electrical detection structures includes a first electrical detection probe and a second electrical detection probe;
wherein, when the chip electrical property detection device is configured to detect a plurality of chips, the chip electrical property detection device is configured to be moved downward through a downward pressure provided by a flexible pressing device, so that the first electrical detection probe and the second electrical detection probe of each of the electrical detection structures respectively and electrically contact two conductive pads of a corresponding one of the chips.

5. The chip electrical property detection device according to claim 1,
wherein each of the electrical detection structures includes a first electrical detection probe and a second electrical detection probe;
wherein the probe carrying substrate includes a plurality of movable carrying plates, and the movable carrying plates are separate from each other and disposed on the flexible buffer material layer;
wherein the first electrical detection probe and the second electrical detection probe of each of the electrical detection structures are respectively disposed on two corresponding ones of the movable carrying plates of the probe carrying substrate;
wherein two adjacent ones of the movable carrying plates are separate from each other by a predetermined distance, and an outer surrounding surface of each of the movable carrying plates is a surrounding cutting surface formed by cutting;
wherein the movable carrying plates are separately disposed on a bottom side of the flexible buffer material layer, and each of the movable carrying plates is configured to be allowed to be slightly adjusted through the flexible buffer material layer, thereby allowing each of the electrical detection structures to be configured to be slightly adjusted following the flexible buffer material layer.

6. A method of manufacturing a chip electrical property detection device, comprising:
providing a structural strengthening module, wherein the structural strengthening module includes a structural strengthening substrate;
providing an electrical detection module, wherein the electrical detection module includes a probe carrying substrate, a plurality of electrical detection structures and a plurality of electrical connection structures;
providing a flexible buffer structure, wherein the flexible buffer structure includes a flexible buffer material layer; and
cooperating the structural strengthening module, the electrical detection module and the flexible buffer structure with each other to form the chip electrical property detection device;
wherein the probe carrying substrate is disposed on the flexible buffer material layer, and the electrical detection structures are respectively disposed on the probe carrying substrate and electrically connected to the electrical connection structures.

7. The method according to claim 6,
wherein each of the electrical detection structures includes a first electrical detection probe and a second electrical detection probe;
wherein the probe carrying substrate is configured to be allowed to be slightly adjusted through the flexible buffer material layer, thereby allowing each of the electrical detection structures to be configured to be slightly adjusted following the probe carrying substrate.

8. The method according to claim 6,
wherein the structural strengthening substrate of the structural strengthening module is configured to carry a plurality of functional chips;
wherein the flexible buffer material layer is configured as a prefabricated polymer material layer, and the prefabricated polymer material layer is a silicone layer or an epoxy layer;
wherein the structural strengthening substrate is configured as a first silicon wafer substrate, and the probe carrying substrate is configured as a second silicon wafer substrate.

9. The method according to claim 6,
wherein each of the electrical detection structures includes a first electrical detection probe and a second electrical detection probe;
wherein, when the chip electrical property detection device is configured to detect a plurality of chips, the chip electrical property detection device is configured to be moved downward through a downward pressure provided by a flexible pressing device, so that the first electrical detection probe and the second electrical detection probe of each of the electrical detection structures respectively and electrically contact two conductive pads of a corresponding one of the chips.

10. The method according to claim 6,
wherein each of the electrical detection structures includes a first electrical detection probe and a second electrical detection probe;
wherein the probe carrying substrate includes a plurality of movable carrying plates, and the movable carrying plates are separate from each other and disposed on the flexible buffer material layer;
wherein the first electrical detection probe and the second electrical detection probe of each of the electrical detection structures are respectively disposed on two corresponding ones of the movable carrying plates of the probe carrying substrate;
wherein two adjacent ones of the movable carrying plates are separate from each other by a predetermined distance, and an outer surrounding surface of each of the movable carrying plates is a surrounding cutting surface formed by cutting;
wherein the movable carrying plates are separately disposed on a bottom side of the flexible buffer material layer, and each of the movable carrying plates is configured to be allowed to be slightly adjusted through the flexible buffer material layer, thereby allowing each of the electrical detection structures to be configured to be slightly adjusted following the flexible buffer material layer.
